(19) United States
(12) Patent Application Publication
(10) Pub. No.: US 2009/0191715 A1
(43) Pub. Date: Jul. 30, 2009

(54) Method for etching interlayer dielectric film

(76) Inventor: Toshio Hayashi, Shizuoka-ken (JP)

Correspondence Address: ARENT FOX LLP, 1050 CONNECTICUT AVENUE, N.W., SUITE 400, WASHINGTON, DC, 20036, US

(21) Appl. No.: 11/663,985

(22) PCT Filed: Mar. 9, 2006
(86) PCT No.: PCT/JP06/04625

§ 371 Date: Feb. 28, 2008

(51) Int. Cl. H01L 21/302

(52) U.S. Cl. 438/710; 257/E21.218

(57) ABSTRACT

In the fine processing of holes and/or trenches by dry-etching an interlayer dielectric film covered with a resist mask formed by ArF-photolithography within a plasma atmosphere, the etching gas used comprises a halogen atom-containing gas (the halogen atom being selected from F, I and/or Br) or a fluorinated carbon atom-containing compound gas in which the ratio of at least one of I and Br is not more than 26% of the total amount of the halogen atoms as expressed in terms of the atomic compositional ratio and the balance of the gas consists of fluorine atoms. Occurrence of striation can be suppressed and a high processing accuracy through etching can be accomplished.

### BACKGROUND OF THE INVENTION

1. Field of the Invention

The present invention relates to a method for dry-etching of an interlayer dielectric film and, more particularly, to a method for dry-etching of an interlayer dielectric film which comprises the step of dry-etching an interlayer dielectric film covered with a resist mask formed using ArF-photolithography to finely process the same and to thus form holes and/or trenches.

2. Description of the Related Art

Recently, the structural details of semiconductor devices have gradually become finer and finer and the layer structure thereof has included more and more layers as the integration density of LSI devices has increased and operational speed thereof has become higher and higher. Photolithography techniques used in the production of these devices frequently include methods using lasers, each emitting a beam having a short wavelength (for instance, an excimer laser). An example is ArF-photolithography. A resist mask provided with a fine pattern can thus be formed. Where an interlayer dielectric film covered with such a resist mask is finely processed by dry-etching to form holes and/or trenches used for wiring or interconnection, a high processing accuracy in the formation of such an etching pattern, is required while ensuring high accuracy or etching consistency in the direction of the depth of the film. In this case, the plasma-etching operation has been carried out while introducing a desired etching gas into the plasma atmosphere in order to ensure a high anisotropy of etching (see, for instance, Patent Document 1 specified below).

The use of a compound free of any benzene ring has been proposed as a resist material used in ArF-photolithography. This compound imparts to the resist material a high sensitivity to light rays whose wavelengths fall within the range of vacuum ultraviolet light rays (see, for instance, Non-Patent Document 1 specified below). When a fine pattern is formed in a resist material of this kind using a laser beam having a short wavelength, the resist mask not only becomes less-durable, but also has a poor plasma-durability compared with that observed for the materials used in other photolithography techniques. This is especially so as the wavelength of the laser beam used becomes shorter and shorter.

For this reason, when etching procedures are carried out in a plasma atmosphere, the resist mask exposed to the plasma atmosphere is damaged, and the edge portions of the patterned regions are, in turn, roughened, thereby deforming the shape of the resist mask. If the etching operation is continued using the resist mask with such defects, various problems arise. That is, the defects are transferred to the holes and/or trenches formed on or through the interlayer dielectric film. This leads to the occurrence of the so-called striation. Consequently, this technique cannot satisfy requirements for highly precise processing through etching.

To solve such a problem, a technique has been proposed comprising the steps of introducing a fluorocarbon gas-containing mixed gas into a low pressure plasma atmosphere and then subjecting an interlayer dielectric film covered with a resist mask formed by ArF-photolithography to dry-etching (see Patent Document 2 specified later).

Patent Document 1: Japanese Un-Examined Patent Publication Hei 11-31678 (see, for instance, Claims);

Patent Document 2: Japanese Patent Application Serial No. 2004-56962 (see, for instance, Claims); and

Non-Patent Document 1: Koji NOZAKI and Ei YANO, FUJITSU Sei. Tech. J., 2002 (June), 38(1): P 3-12.

### SUMMARY OF THE INVENTION

The above-described second technique could permit the control of the generation of striation by practicing the dry-etching while introducing a desired mixed gas into the etching zone at a low pressure. Also, the achievement of a high processing accuracy through etching can be accomplished. However, only a small number of etching apparatuses can provide stable discharge conditions under a pressure lower than a predetermined level (for instance, 0.133 Pa). Consequently, such a dry-etching technique cannot widely be adopted.

In light of the foregoing description concerning the conventional techniques, it is thus an aspect of the present invention to provide a method for dry-etching an interlayer dielectric film which can inhibit the occurrence of striation and which permits the achievement of a high processing accuracy through etching.

The present invention herein provides a method for dry-etching an interlayer dielectric film to solve the foregoing problems. The method comprises the step of dry-etching an interlayer dielectric film covered with a resist mask formed by ArF-photolithography in a plasma atmosphere while introducing a desired etching gas into the plasma atmosphere to thus finely process the dielectric film and to thereby form holes and/or trenches. The method is characterized in that the etching gas used comprises a halogen atom-containing gas (the halogen atom being selected from F, I and/or Br) or a fluorinated carbon atom-containing compound gas in which the ratio of at least one of I and Br is not more than 26% of the total amount of the halogen atoms as expressed in terms of the atomic compositional ratio and the balance of the gas consists of fluorine atoms.

According to the dry-etching method of the present invention, the etching gas used is a fluorinated carbon atom-containing compound gas comprising at least one member selected from the group consisting of I and Br which form quite stable compounds and do, in themselves, function as etchants for Si. Accordingly, the present invention permits the reduction of the fluorine atom density within the plasma atmosphere independent of the working pressure during etching to thereby protect the resist mask from the significant attack of the etching gas and to control the generation of striation. If the ratio of at least one of I and Br exceeds 26% of the total amount of the halogen atoms present in the etching gas as expressed in terms of the atomic compositional ratio, a variety of troubles occur. For example, the etching rate is lowered and any desired etching pattern cannot be obtained through the dry-etching treatment.

The foregoing fluorinated carbon atom-containing compound gas is preferably either an iodinated and fluorinated carbon atom-containing compound gas or a brominated and fluorinated carbon atom-containing compound gas or a mixture thereof.

In this case, the foregoing iodinated and fluorinated carbon atom-containing compound gas may be at least one member selected from the group consisting of CF₃I, C₂F₅I, C₃F₇I and C₃F₆I₂, or a mixed gas comprising HI or HBr and at least one of the foregoing iodinated and fluorinated carbon atom-containing compound gas.

In addition, the foregoing brominated and fluorinated carbon atom-containing compound gas may be at least one member selected from the group consisting of CF₃Br, C₂F₅Br, C₃F₇Br and C₃F₆Br₂, or a mixed gas comprising HI or HBr and at least one of the foregoing brominated and fluorinated carbon atom-containing compound gas.

In this connection, the etching gas used herein may likewise be a mixed gas comprising CF₄ and C₂F₄I₂ or C₂F₄Br₂.

The etching gas used herein may be a mixed gas comprising at least one of HI and HBr, and a perfluoro-carbon-containing compound.

The etching gas used herein may be a mixed gas comprising CF₃I and a perfluoro-carbon-containing compound.

The etching gas used herein may be a mixed gas comprising CF₃Br and a perfluoro-carbon-containing compound.

In the present invention, it is sufficient to add oxygen to the etching gas in an amount ranging from about 3 to 15% on the basis of the total flow rate of the gas to be introduced into the etching chamber in order to prevent the filling up of the holes and/or trenches formed by the etching operations while adjusting the amount of the deposition comprising the reaction products formed during etching. In this case, if the amount of oxygen added to the etching gas is less than 3%, the desired effect of the present invention described above cannot be accomplished and the amount of the deposition cannot be controlled. On the other hand, if the amount of oxygen exceeds 15%, the ArF resist would be over-etched and thus damaged through the etching procedures.

As has been described above, the dry-etching method of an interlayer dielectric film according to the present invention permits the achievement of excellent effects such that it can inhibit the occurrence of striation and such that it can ensure the achievement of a high processing accuracy through etching.

### BRIEF DESCRIPTION OF THE DRAWINGS

FIG. 1 is a diagram schematically showing an etching apparatus used for practicing the method for etching an interlayer dielectric film according to the present invention.

FIGS. 2(a) to 2(c) are diagrams for schematically illustrating the occurrence of striation.

FIGS. 3(a) to 3(c) are SEM images of an interlayer dielectric film processed in three different etching steps according to the method described in Example 1.

FIGS. 4(a) to 4(c) are SEM images of an interlayer dielectric film processed in three different etching steps according to the method described in Comparative Example 1.

### DETAILED DESCRIPTION OF THE PREFERRED EMBODIMENTS

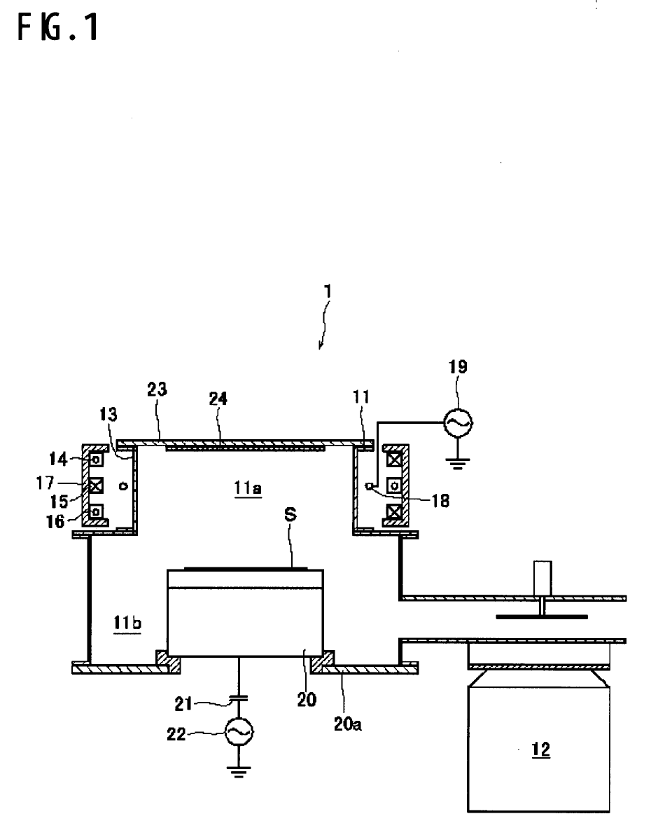

Referring now to the attached FIG. 1, an etching apparatus 1 used in the present invention for the dry-etching of an interlayer dielectric film and for the formation of holes and/or trenches for wiring through fine processing is shown. This etching apparatus 1 uses an electric discharge plasma (NLD plasma) generated within a region including zero magnetic field areas. The apparatus 1 is equipped with a vacuum chamber 11 provided with an evacuation means 12, such as a dry pump, a rotary pump and/or a turbo molecular pump, and the like.

The chamber 11 comprises an upper plasma-generation compartment 11a having a cylindrical side wall 13 made of a dielectric material, such as quartz, and a lower substrate-processing compartment 11b. Three magnetic field-establishing coils 14, 15 and 16 are arranged on the exterior of the cylindrical side wall 13 at predetermined intervals to thus constitute a magnetic field-generation means. These three magnetic field-establishing coils 14, 15 and 16 are fitted in such a manner to a yoke member 17 having a high magnetic permeability that the yoke member externally surrounds these coils including the upper and lower sides thereof. Electric currents are concurrently applied to the respective upper and lower magnetic field-establishing coils 14 and 16, while an electric current is counter-currently passed through the intermediate magnetic field-establishing coil 15. Thus, a continuous zero magnetic field zone is formed on the inside of the cylindrical side wall 13 and in proximity to the intermediate coil 15, forming, in this manner, an annular magnetic neutral line or loop.

The size of the annular magnetic neutral loop can properly be set at a desired level by variously changing the ratio of the electric current applied to the upper and lower magnetic field-establishing coils 14 and 16 to the electric current applied to the intermediate magnetic field-establishing coil 15. The upper and lower positions of the annular magnetic neutral loop can likewise be set at a desired level by properly selecting the ratio of the electric current applied to the upper magnetic field-establishing coil 14 to the electric current applied to the lower magnetic field-establishing coil 16. In addition, when the electric current applied to the intermediate magnetic field-establishing coil 15 is gradually increased, the diameter of the resulting annular magnetic neutral loop decreases, and the gradient of the magnetic field observed at the zero magnetic field position is simultaneously reduced gently and gradually. An antenna 18 for the generation of a high-frequency electric field is positioned between the intermediate magnetic field-establishing coil 15 and the cylindrical side wall 13. The antenna 18 is connected to a high-frequency power source 19 to thus constitute a magnetic field-generating means. In this way, an NLD plasma can thus be generated along the annular magnetic neutral loop formed by the three magnetic field-establishing coils 14, 15 and 16.

Within the substrate processing compartment 11b, a substrate electrode 20 is provided on an insulating material 20a. The substrate electrode 20 has a circular cross-section and serves as a substrate-mounting part on which a substrate S to be processed is positioned in such a manner that the substrate faces the plane formed by the annular magnetic neutral loop. This substrate electrode 20 is connected to the second high-frequency power source 22 through a condenser 21 and serves as a floating electrode from the viewpoint of the electric potential to thus generate or establish a negative bias voltage.

A roof or lid 23 defining the plasma-generation compartment 11a is tightly fitted to the upper portion of the cylindrical side wall 13 to thus constitute a counter electrode which is potentially in a floated condition. A gas-introduction means 24 is arranged on the inner wall of the roof for introducing an etching gas into the chamber 11. The gas-introduction means 24 is connected to a gas source (not shown) through a gas flow rate-controlling means (not shown).

Examples of interlayer dielectric films to be subjected to the fine processing of holes and/or trenches for wiring using the etching apparatus 1 include films of oxides such as SiO₂, SiOCH-type materials formed through spin-coating such as HSQ and MSQ, and SiOC-type materials formed by the CVD technique, which are Low-k materials, each having a relative dielectric constant ranging from 1.5 to 3.0, including porous materials.

Examples of such SiOCH-type materials include one available from Catalysts & Chemicals Industries, Co., Ltd. under the trade name of NCS; one available from JSR Company under the trade name of LKD 5109r5; one available from Hitachi Chemical Co., Ltd. under the trade name of HSG-7000; one available from Honeywell Electric Materials Company under the trade name of HOSP; one available from Honeywell Electric Materials Company under the trade name of Nanoglass; one available from Tokyo Ohka Kogyo Co., Ltd. under the trade name of OCD T-12; one available from Tokyo Ohka Kogyo Co., Ltd. under the trade name of OCD T-32; one available from Catalysts & Chemicals Industries, Co., Ltd. under the trade name of IPS2.4; one available from Catalysts & Chemicals Industries, Co., Ltd. under the trade name of IPS2.2; one available from Asahi Chemical Industry Co., Ltd. under the trade name of ALCAP-S5100; and one available from ULVAC Company under the trade name of ISM.

Examples of such SiOC-type materials include one available from Nippon ASM Co., Ltd. under the trade name of Aurola2.7; one available from Nippon ASM Co., Ltd. under the trade name of Aurola2.4; one available from TRICON Company under the trade name of Orion2.7; one available from Novellf Company under the trade name of Coral; and one available from AMAT Company under the trade name of Black Diamond. Usable materials for the interlayer dielectric films may likewise be, for instance, materials for forming organic-type low dielectric interlayer dielectric films such as one available from Dow Chemical Company under the trade name of SiLK; one available from Dow Chemical Company under the trade name of Porous-SiLK; one available from Honeywell Electric Materials Company under the trade name of FLARE; one available from Honeywell Electric Materials Company under the trade name of Porous FLARE; and one available from Honeywell Electric Materials Company under the trade name of GX-3P.

A resist mask having a predetermined pattern is formed on the interlayer dielectric film by photolithography in order to form holes and/or trenches for wiring through the fine processing operations. As such, a photolithography technique, for instance, ArF-photolithography, can be used in order to produce semiconductor devices that have finer and finer structural detail and more and more layers as the integration density of LSI devices has increased and the operational speed thereof has become higher and higher. For instance, UV-6 for vacuum ultraviolet light rays available from Shipley Company has been known as a resist material for ArF-photolithography.

The resist material used in ArF-photolithography is sometimes a compound free of any benzene ring. This compound imparts to the resulting resist mask a high sensitivity to light rays whose wavelengths fall within the range of vacuum ultraviolet light rays. When a fine pattern is formed in a resist material of this kind using a laser beam having a short wavelength, the resist mask not only becomes less-durable, but also has a poor plasma-resistance compared with that observed for the materials used in other photolithography techniques. This is especially so as the wavelength of the laser beam used becomes shorter and shorter.

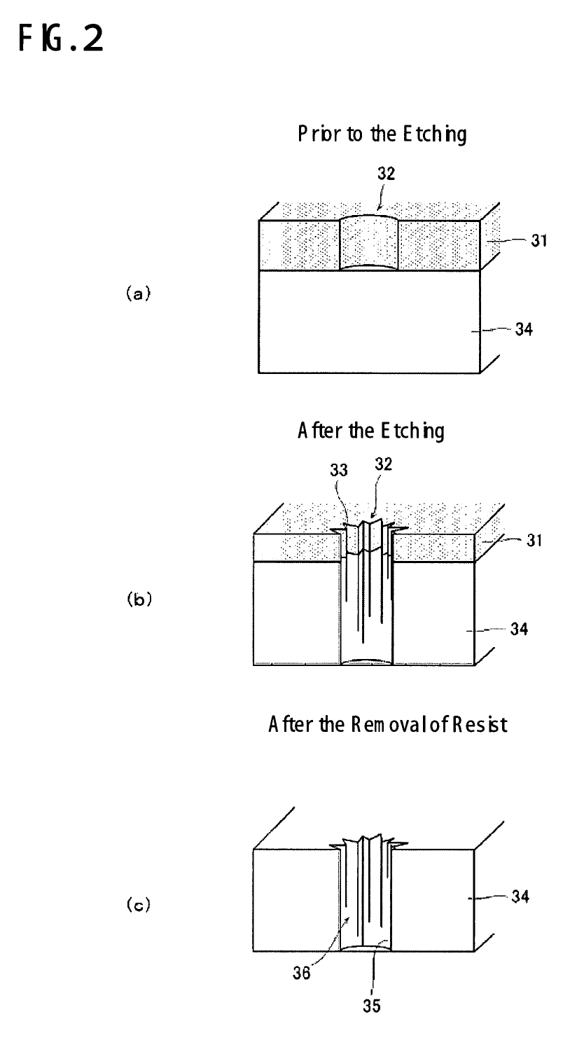

When etching an interlayer dielectric film using the conventional dry-etching method adopted for etching such an interlayer dielectric film, for instance, in an inductively coupled plasma (ICP plasma) etching system (not shown), an etching gas containing a fluorocarbon (CₓF_{y}) is introduced into the plasma atmosphere under a working pressure ranging from 1 to 3 Pa. The Ar plasma density is about 1×10¹¹ cm⁻³. As will be seen from FIG. 2b, the resist mask 31 exposed to the plasma atmosphere is damaged. The edge portions 32 of the patterned regions thereof are roughened because the shape of the resist mask 31 is deformed as can be seen at reference number 33. If the etching operation is continued using the resist mask carrying such defects, various problems arise such that the defects are also transferred to the holes and/or trenches 35 formed on or through the interlayer dielectric film 34. This leads to the occurrence of the so-called striation 36. Accordingly, this technique cannot satisfy requirements for highly precise processing through etching.

It has, in general, been recognized that the reason why the foregoing striation 36 occurs is that the resist mask is damaged by the ions during the etching within the plasma atmosphere. In light of such recognition, it would be believed from the following reasons that a striation phenomenon likewise occurs even when the etching of the interlayer dielectric film is carried out using the above-described NLD plasma etching apparatus 1 which makes use of a low pressure and high density plasma.

More specifically, in the NLD plasma etching apparatus 1, the etching conditions used are, in general, as follows: a working pressure ranging from 0.3 to 0.7 Pa; an output of the high-frequency power source 19 connected to the antenna 18 ranging from 1 to 1.5 kW; an output (bias power) of the second high-frequency power source 22 ranging from 0.2 to 0.6 kW; and the Ar plasma density set at a level of about 1×10¹¹ cm⁻³. In this case, the working pressure is set at a level lower than that used in the conventional methods. Accordingly, the plasma density is reduced, but within the etching apparatus 1 an efficient discharge plasma is established in the form of an annular magnetic neutral loop. Therefore, the plasma density is only slightly reduced.

For this reason, the ionic current density within the etching apparatus 1 would be almost identical to that observed for the conventional ICP plasma etching apparatus which cannot control the occurrence of striation. The ion energy is about 1 KeV when the output of the second high-frequency power source 22 is set at a level of 0.3 kW. Accordingly, high energy ions certainly collide with the resist mask 31. Thus, it would be believed that striation would occur when etching an interlayer dielectric film using the NLD plasma etching apparatus 1.

Some situations have been known in which the occurrence of striation can be controlled by reducing the working pressure to a level of not higher than a predetermined value even when using the ICP plasma etching apparatus. This is because the physical quantity of the neutral decomposition species (such as atoms, molecules and radicals) is reduced since the working pressure is set at a low level. In this case, the species generated through the decomposition of the CₓF_{y} gas include, for instance, F, CF, CF₂, CF₃, and the like, and among them, the molecular radicals mainly serve as polymerization precursors. However, these species have only a poor function as substances for etching the resist mask 31. From the foregoing, the F atom which is highly reactive with organic substances takes part in the reactions with the C═O groups and other functional groups present on or in the resist mask 31 to thus make the resist mask 31 less-durable. Thus, such a radical reaction would be a cause of the embrittlement of the resist mask 31.

In the dry-etching of a porous Low-k film, a phenomenon has been discovered that when the etching operation is carried out using C₃F₇I as an etching gas under low pressure and high plasma density conditions, the etching rate of the resist mask is reduced, while the selectivity of the etching gas against the resist mask is improved. The reason for such a reduction of the etching rate is that the F radicals serving as an etchant for the resist mask undergo a reaction with I present in the gas phase to thus form, for instance, IF₃, IF₅, IF₇ and the like.

As has been discussed above, the occurrence of striation of the resist mask can be controlled or eliminated by setting the working pressure of the etching operation at a low level even when the etching is carried out using an ICP plasma etching apparatus. The reason for this is that the density of F atoms as an etchant for the resist mask is reduced among other radical species present in the etching chamber. Moreover, if using a gas containing iodine atoms as an etching gas, the iodine can serve as a scavenger for F atoms and this correspondingly leads to the reduction of the etching rate of the resist mask. For the foregoing reasons, it would be quite important to reduce the density of F atoms within the etching chamber or the plasma atmosphere through the use of iodine atoms or any other means for trapping F atoms present therein to thus convert them into stable compounds in order to certainly control the occurrence of striation.

In light of the foregoing description, it would be concluded that the etching operation should be carried out while using, as an etching gas, a gas containing a substance which can undergo a reaction with F atoms to thus give a stable compound and which never adversely affects the etching mechanism per se, such as H, Br, I and/or Xe. In this connection, a hydrogen atom may not only undergo a fast reaction with fluorine atoms to thus form HF molecules but also react with organic compounds. Therefore, control of these reactions would be quite difficult. In addition, Xe reacts with F to form an excited dimer whose bond strength is accordingly quite weak. Further, the element is quite expensive. Accordingly, the use thereof is impracticable. On the other hand, Br and I atoms not only can form stable compounds such as IF₃, IF₅, IF₇, BrF₃, BrF₅, but also have, in themselves, a function as an etchant for Si and never adversely affect the etching reaction per se.

Accordingly, this embodiment of the present invention employs, as an etching gas, a halogen atom-containing gas (the halogen atom being selected from F, I and/or Br) and, more particularly, a fluorinated carbon atom-containing compound gas in which the ratio of at least one of I and Br is not more than 26% of the total amount of the halogen atoms as expressed in terms of the atomic compositional ratio, and the balance of the gas consists of fluorine atoms. In particular, the present invention employs either an iodinated and fluorinated carbon atom-containing compound gas or a brominated and fluorinated carbon atom-containing compound gas, or mixtures thereof.

These iodinated and fluorinated carbon atom-containing compound gases and/or brominated and fluorinated carbon atom-containing compound gases are preferably those represented by the general formula: Cₙ(Hal)₂ₙ₊₂ (in the formula, Hal means a halogen atom and n is a number ranging from 1 to 3). Preferably used herein are, for instance, at least one member selected from the group consisting of CF₃I, CF₃Br, C₂F₅I, C₂F₅Br, C₃F₇I, C₃F₇Br, C₃F₆I₂ and C₃F₆Br₂, or mixed gases each comprising HI or Br, and at least one member selected from the group consisting of these fluorinated carbon atom-containing compound gases. The use of such an etching gas wherein n is higher than 3 is not practical since a problem arises such that the interior of the chamber 11 is contaminated during etching.

Moreover, other usable etching gases also include, for instance, iodinated and fluorinated carbon atom-containing compound gases such as C₂F₄I₂ and brominated and fluorinated carbon atom-containing compound gases such as C₂F₄Br₂. In this case, CF₄ gas or the like is added to the etching gas in such a manner that the ratio of I and/or Br in the gas thus obtained is not more than 26% of the total amount of the halogen as expressed in terms of the atomic compositional ratio.

Furthermore, the etching gas may be a mixed gas comprising at least one of HI and HBr, and a perfluoro carbon-containing compound, such as tetrafluoroethylene, represented by the general formula: Cₙ(Hal)₂ₙ (in the formula, Hal means a halogen atom and n is a number ranging from 1 to 3). Examples of etching gases usable herein also include a mixed gas comprising CF₃I and a perfluoro carbon-containing compound; and a mixed gas comprising CF₃Br and a perfluoro carbon-containing compound.

Thus, the F atom density in the plasma atmosphere within the etching chamber 11 can be reduced independent of the pressure used during the etching step within the chamber 11 to thus protect the resist mask from any damage and to thereby control or eliminate the occurrence of any striation. In this case, however, if the ratio of at least one of I and Br exceeds 26% of the total amount of the halogen atoms as expressed in terms of the atomic compositional ratio, several problems arise such that the etching rate is reduced and any desired etching pattern cannot be obtained.

In addition, a small amount of oxygen gas may be added to the foregoing fluorinated carbon atom-containing compound gas in order to prevent the filling up of the holes and/or trenches formed by the etching operations while adjusting the amount of the deposition comprising the reaction products formed during the etching procedures.

In this case, the amount of oxygen gas to be added to the chamber 11 is set at a level ranging from about 3 to 15%, preferably 3 to 10%, and, more preferably, 4 to 7% on the basis of the total flow rate of the gas to be introduced into the etching chamber 11. This is because if the amount of oxygen added thereto is less than 3%, the desired effect of the present invention described above cannot be accomplished and the amount of the deposition cannot be controlled. On the other hand, if the amount of oxygen exceeds 15%, the ArF resist mask itself would be etched, and accordingly, damaged through the etching procedures.

### Example 1

In Example 1, an SiO₂ film was used as an interlayer dielectric film. The film was formed on a substrate to be processed in a film thickness of 1000 nm using a spin-coater. Then, a resist material was coated on the interlayer dielectric film using a spin-coater, followed by the formation of a desired pattern using ArF-photolithography to thus form a resist mask. In this case, the resist material used was UV-6 for vacuum ultraviolet light rays and the thickness of the resist mask was set at 500 nm.

Subsequently, the foregoing interlayer dielectric film was etched by introducing Ar gas and C₃F₇I as an etching gas into the vacuum chamber 11 of the NLD plasma etching apparatus 1, as shown in FIG. 1, at a working pressure of 2.67 Pa to thus form holes. At this stage, the flow rates of Ar, C₃F₇I gas and oxygen gas were set at levels of 230 sccm, 50 sccm and 20 sccm, respectively. Etching was carried out by setting the output of the high-frequency power source 19 connected to the high-frequency antenna coil 18 for the generation of the plasma used herein at 1 kW, by setting the output of the high-frequency power source 22 connected to the substrate electrode 21 at a level of 0.3 kW and by setting the substrate temperature at 10° C.

### Comparative Example 1

In Comparative Example 1, an interlayer dielectric film and a resist mask were formed under the same conditions used in Example 1 and the etching of the interlayer dielectric film was likewise carried out under the same conditions used in Example 1 using the NLD plasma etching apparatus 1 as shown in FIG. 1. In this case, however, C₃F₈ gas was substituted for the C₃F₇I gas used in Example 1 as the etching gas.

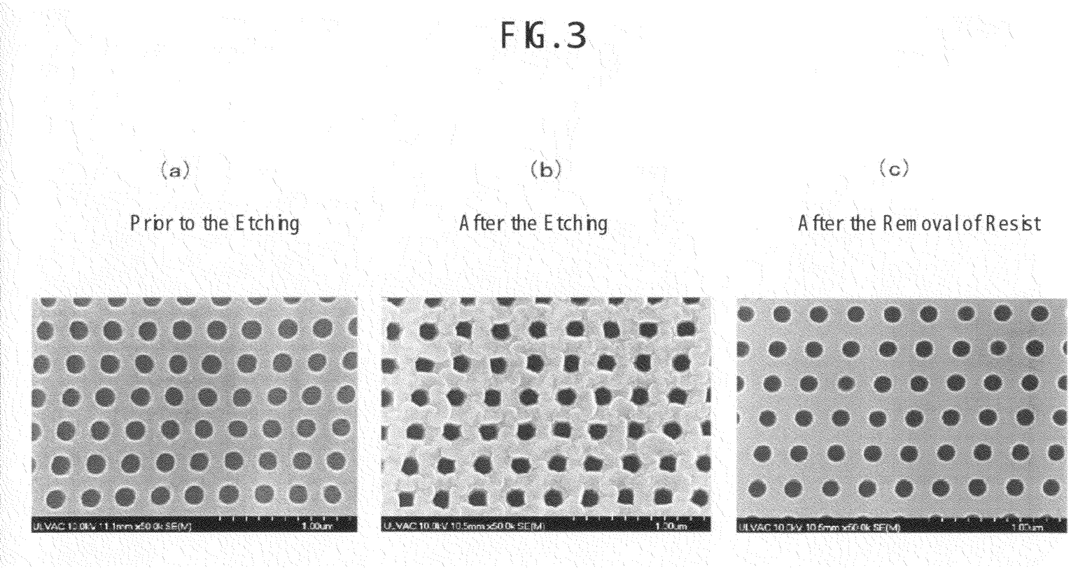

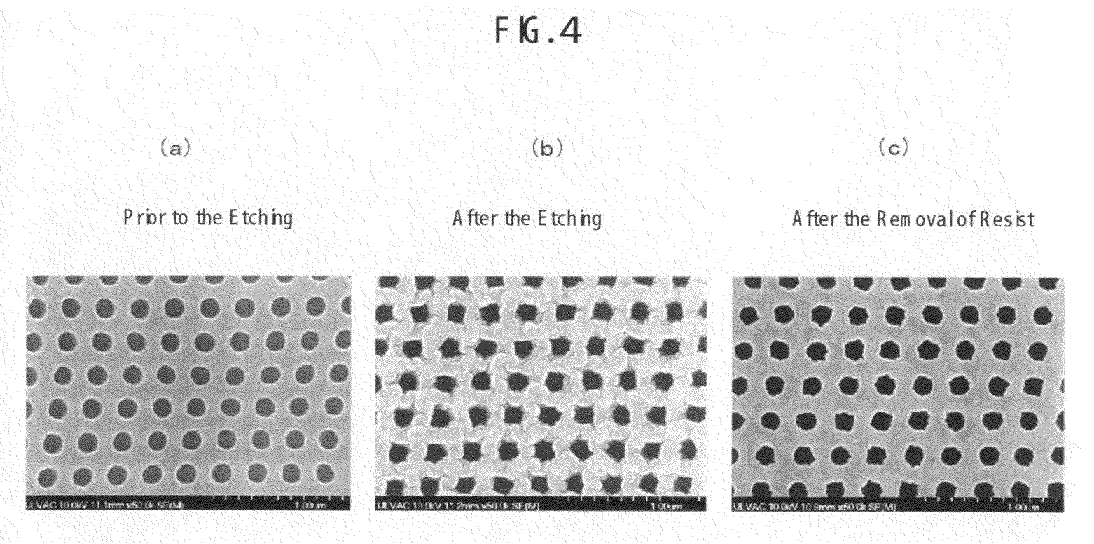

FIGS. 3 and 4 are SEM images showing the interlayer dielectric films etched under the conditions used in Example 1 and Comparative Example 1, respectively. As can be seen from these figures, in the case of the product prepared in Comparative Example 1, it was confirmed that the resist mask was damaged by the etching, that the edge portions of the patterned regions thereof were in turn roughened and that the holes thus formed suffered from striation (see, FIGS. 4(b) and 4(c)). Contrary to this, it can be seen that the product of Example 1 was protected from the roughening of the hole-edges and that the occurrence of striation could be controlled (see, FIGS. 3(b) and 3(c)).

Separately, an interlayer dielectric film and a resist mask were formed under the same conditions used in Example 1, and etching of the interlayer dielectric film was likewise carried out under the same conditions used in Example 1 using the etching apparatus 1, as shown in FIG. 1, except that the pressure in the etching chamber 11 was set at 0.67 Pa. In this case, the etching rate was slightly improved and the occurrence of striation could be suppressed. In addition, Br was substituted for the I used in Example 1, but the same results were obtained.

Incidentally, the NLD plasma etching apparatus would permit the application of a weak magnetic field to the etching chamber and thus permit the efficient formation of a plasma at a pressure of not more than 1 Pa. However, if the pressure exceeds 1 Pa, the mean free path of each electron is shortened and the apparatus does not form NLD plasma but forms an ICP plasma. For this reason, Example 1 was carried out using the NLD plasma etching apparatus 1, but the pressure used is not less than 1 Pa and, accordingly, any effect of such a magnetic field cannot be expected or the resulting plasma is one formed under the zero magnetic field condition. Accordingly, the resulting plasma is identical to that generated by the ICP technique. Therefore, the effect of the present invention is not dependent upon the structure of the etching apparatus used but dependent upon the plasma density and the composition of the etching gas used. As a result, the plasma generated according to the present invention has a density ranging from 10¹⁰ to 10¹¹ cm⁻³ and, accordingly, it would, in principle, be clear that the same results discussed above can be obtained for any interlayer dielectric film covered with the ArF-resist mask.

1-9. (canceled)

10. A dry-etching method of an interlayer dielectric film comprising the step of subjecting an interlayer dielectric film covered with a resist mask formed by ArF-photolithography to dry-etching in a plasma atmosphere while introducing a desired etching gas into the plasma atmosphere to finely process the interlayer dielectric film and to thus form holes and/or trenches, wherein the etching gas used comprises a halogen atom-containing gas, the halogen atom being selected from F, I and/or Br, or a fluorinated carbon atom-containing compound gas in which the ratio of at least one of I and Br is not more than 26% of the total amount of the halogen atoms as expressed in terms of the atomic compositional ratio and the balance of the gas consists of fluorine atoms.

11. The dry-etching method of an interlayer dielectric film as set forth in claim 10, wherein the fluorinated carbon atom-containing compound gas is either an iodinated and fluorinated carbon atom-containing compound gas or a brominated and fluorinated carbon atom-containing compound gas or a mixture thereof.

12. The dry-etching method of an interlayer dielectric film as set forth in claim 11, wherein the iodinated and fluorinated carbon atom-containing compound gas is at least one member selected from the group consisting of CF₃I, C₂F₅I, C₃F₇I and C₃F₆I₂, or a mixed gas comprising HI or HBr and at least one of said iodinated and fluorinated carbon atom-containing compound gases.

13. The dry-etching method of an interlayer dielectric film as set forth in claim 11, wherein the brominated and fluorinated carbon atom-containing compound gas is at least one member selected from the group consisting of CF₃Br, C₂F₅Br, C₃F₇Br and C₃F₆Br₂, or a mixed gas comprising HI or HBr and at least one of said brominated and fluorinated carbon atom-containing compound gases.

14. The dry-etching method of an interlayer dielectric film as set forth in claim 10, wherein the etching gas is a mixed gas comprising CF₄ and C₂F₄I₂ or C₂F₄Br₂.

15. The dry-etching method of an interlayer dielectric film as set forth in claim 11, wherein the etching gas is a mixed gas comprising CF₄ and C₂F₄I₂ or C₂F₄Br₂.

16. The dry-etching method of an interlayer dielectric film as set forth in claim 10, wherein the etching gas is a mixed gas comprising at least one of HI and HBr, and a perfluoro-carbon-containing compound.

17. The dry-etching method of an interlayer dielectric film as set forth in claim 11, wherein the etching gas is a mixed gas comprising at least one of HI and HBr, and a perfluoro-carbon-containing compound.

18. The dry-etching method of an interlayer dielectric film as set forth in claim 11, wherein the etching gas is a mixed gas comprising at least one of HI and HBr, and a perfluoro-carbon-containing compound.

19. The dry-etching method of an interlayer dielectric film as set forth in claim 11, wherein the etching gas is a mixed gas comprising at least one of HI and HBr, and a perfluoro-carbon-containing compound.

20. The dry-etching method of an interlayer dielectric film as set forth in claim 10, wherein the etching gas is a mixed gas comprising CF₃I and a perfluoro-carbon-containing compound.

21. The dry-etching method of an interlayer dielectric film as set forth in claim 11, wherein the etching gas is a mixed gas comprising CF₃I and a perfluoro-carbon-containing compound.

22. The dry-etching method of an interlayer dielectric film as set forth in claim 11, wherein the etching gas is a mixed gas comprising CF₃I and a perfluoro-carbon-containing compound.

23. The dry-etching method of an interlayer dielectric film as set forth in claim 11, wherein the etching gas is a mixed gas comprising CF₃I and a perfluoro-carbon-containing compound.

24. The dry-etching method of an interlayer dielectric film as set forth in claim 10, wherein the etching gas is a mixed gas comprising CF₃Br and a perfluoro-carbon-containing compound.

25. The dry-etching method of an interlayer dielectric film as set forth in claim 10, wherein the etching gas is a mixed gas comprising CF₃Br and a perfluoro-carbon-containing compound.

26. The dry-etching method of an interlayer dielectric film as set forth in claim 11, wherein the etching gas is a mixed gas comprising CF₃Br and a perfluoro-carbon-containing compound.

27. The dry-etching method of an interlayer dielectric film as set forth in claim 11, wherein the etching gas is a mixed gas comprising CF₃Br and a perfluoro-carbon-containing compound.

28. The dry-etching method of an interlayer dielectric film as set forth in claim 10, wherein oxygen gas is incorporated into the etching gas in an amount ranging from about 3 to 15% on the basis of the total flow rate of the etching gas.

29. The dry-etching method of an interlayer dielectric film as set forth in claim 10, wherein oxygen gas is incorporated into the etching gas in an amount ranging from about 3 to 15% on the basis of the total flow rate of the etching gas.

30. The dry-etching method of an interlayer dielectric film as set forth in claim 11, wherein oxygen gas is incorporated into the etching gas in an amount ranging from about 3 to 15% on the basis of the total flow rate of the etching gas.

31. The dry-etching method of an interlayer dielectric film as set forth in claim 11, wherein oxygen gas is incorporated into the etching gas in an amount ranging from about 3 to 15% on the basis of the total flow rate of the etching gas.

32. The dry-etching method of an interlayer dielectric film as set forth in claim 10, wherein oxygen gas is incorporated into the etching gas in an amount ranging from about 3 to 15% on the basis of the total flow rate of the etching gas.

33. The dry-etching method of an interlayer dielectric film as set forth in claim 11, wherein oxygen gas is incorporated into the etching gas in an amount ranging from about 3 to 15% on the basis of the total flow rate of the etching gas.

34. The dry-etching method of an interlayer dielectric film as set forth in claim 10, wherein oxygen gas is incorporated into the etching gas in an amount ranging from about 3 to 15% on the basis of the total flow rate of the etching gas.

35. The dry-etching method of an interlayer dielectric film as set forth in claim 11, wherein oxygen gas is incorporated into the etching gas in an amount ranging from about 3 to 15% on the basis of the total flow rate of the etching gas.

36. The dry-etching method of an interlayer dielectric film as set forth in claim 11, wherein oxygen gas is incorporated into the etching gas in an amount ranging from about 3 to 15% on the basis of the total flow rate of the etching gas.

37. The dry-etching method of an interlayer dielectric film as set forth in claim 11, wherein oxygen gas is incorporated into the etching gas in an amount ranging from about 3 to 15% on the basis of the total flow rate of the etching gas.

38. The dry-etching method of an interlayer dielectric film as set forth in claim 10, wherein oxygen gas is incorporated into the etching gas in an amount ranging from about 3 to 15% on the basis of the total flow rate of the etching gas.

39. The dry-etching method of an interlayer dielectric film as set forth in claim 11, wherein oxygen gas is incorporated into the etching gas in an amount ranging from about 3 to 15% on the basis of the total flow rate of the etching gas.

40. The dry-etching method of an interlayer dielectric film as set forth in claim 11, wherein oxygen gas is incorporated into the etching gas in an amount ranging from about 3 to 15% on the basis of the total flow rate of the etching gas.

41. The dry-etching method of an interlayer dielectric film as set forth in claim 11, wherein oxygen gas is incorporated into the etching gas in an amount ranging from about 3 to 15% on the basis of the total flow rate of the etching gas.

42. The dry-etching method of an interlayer dielectric film as set forth in claim 10, wherein oxygen gas is incorporated into the etching gas in an amount ranging from about 3 to 15% on the basis of the total flow rate of the etching gas.

43. The dry-etching method of an interlayer dielectric film as set forth in claim 10, wherein oxygen gas is incorporated into the etching gas in an amount ranging from about 3 to 15% on the basis of the total flow rate of the etching gas.

44. The dry-etching method of an interlayer dielectric film as set forth in claim 11, wherein oxygen gas is incorporated into the etching gas in an amount ranging from about 3 to 15% on the basis of the total flow rate of the etching gas.

45. The dry-etching method of an interlayer dielectric film as set forth in claim 11, wherein oxygen gas is incorporated into the etching gas in an amount ranging from about 3 to 15% on the basis of the total flow rate of the etching gas.

46. An etching apparatus for subjecting an interlayer dielectric film covered with a resist mask carrying patterns formed by ArF-photolithography to dry-etching in a plasma atmosphere, comprising a gas-introduction means connected to a gas source through a gas flow rate-controlling means, the apparatus being constructed as to introduce an etching gas into a chamber through the gas-introduction means while etching the interlayer dielectric film, wherein the etching gas comprises a halogen atom-containing gas, the halogen atom being selected from F, I and/or Br, or a fluorinated carbon atom-containing compound gas in which the ratio of at least one of I and Br is not more than 26% of the total amount of the halogen atoms as expressed in terms of the atomic compositional ratio and the balance of the gas consists of fluorine atoms.
